(19) United States
(12) Patent Application Publication
(10) Pub. No.: US 2015/0060859 A1
(43) Pub. Date: Mar. 5, 2015

(54) EVALUATION SAMPLE, METHOD OF OBTAINING ETCHING YIELD FUNCTION AND SIMULATION METHOD

(71) Applicant: Kabushiki Kaisha Toshiba, Minato-ku (JP)

(72) Inventor: Ryota NIHEI, Yokkaichi-Shi (JP)

(73) Assignee: Kabushiki Kaisha Toshiba, Minato-ku (JP)

(21) Appl. No.: 14/147,753

(22) Filed: Jan. 6, 2014

Related U.S. Application Data
(60) Provisional application No. 61/873,508, filed on Sep. 4, 2013.

(51) Int. Cl. H01L 21/66; G06F 17/50; H01L 21/3065; H01L 29/04

(52) U.S. Cl. CPC H01L 22/20; H01L 29/04; G06F 17/5009; H01L 21/3065; G06F 2217/12
USPC 257/64; 438/9; 716/56

(57) ABSTRACT

In accordance with an embodiment, an evaluation sample includes a substrate and a polycrystalline film on the substrate. The polycrystalline film has crystal grains. A specific orientation plane is exposed on the surface of each crystal grain. The orientation planes exhibit random angles to the surface of the substrate.

### CROSS REFERENCE TO RELATED APPLICATIONS

This application is based upon and claims the benefit of U.S. provisional Application No. 61/873,508, filed on Sep. 04, 2013, the entire contents of which are incorporated herein by reference.

### FIELD

Embodiments described herein relate generally to an evaluation sample, a method of obtaining an etching yield function, and a simulation method.

### BACKGROUND

In a manufacturing process of a device such as a semiconductor circuit device, the surface structure after an etching treatment is predicted by computer simulation. The results of computer simulation are fed back to the etching process or the processes before it to shorten the development period and reduce the development cost.

In order to accurately predict the surface structure by computer simulation for an etching process such as reactive ion etching (RIE), it is necessary to determine the etching yield function. The etching yield function is a function representing an etching rate at which a material is etched regarding the angles between the surface of the material layer and a substrate surface, ranging from 0° to 90°.

It has heretofore been difficult to accurately determine the etching yield function.

### BRIEF DESCRIPTION OF THE DRAWINGS

In the accompanying drawings:

FIG. 1 is an example of a schematic sectional view illustrating an evaluation sample according to an embodiment;

FIG. 2A to FIG. 2C are examples of schematic sectional views illustrating a method of manufacturing the evaluation sample shown in FIG. 1;

FIG. 3 is an example of a flowchart showing a general process of determining a yield function according to an embodiment;

FIG. 4A to FIG. 4C are examples of schematic sectional views illustrating a method of determining the yield function shown in FIG. 3; and

FIG. 5 is an example of a flowchart showing a general procedure of a simulation method according to an embodiment.

### DETAILED DESCRIPTION

In accordance with an embodiment, an evaluation sample includes a substrate and a polycrystalline film on the substrate. The same crystal-orientated plane is exposed on the surface of each crystal grain. Each orientation plane exhibits a random angle to the surface of the substrate.

Embodiments will now be explained with reference to the accompanying drawings. The same components are provided with the same reference signs throughout the drawings and repeated descriptions thereof are appropriately omitted. What will be explained in the following is described in the aspect of manufacturing semiconductor devices, but the present invention is not limited thereto and is applicable to devices in general that are manufactured with an etching fabrication process. It is to be noted in the present application that the term “about” is used to include measurement errors.

(A) Evaluation Sample

(1) Configuration

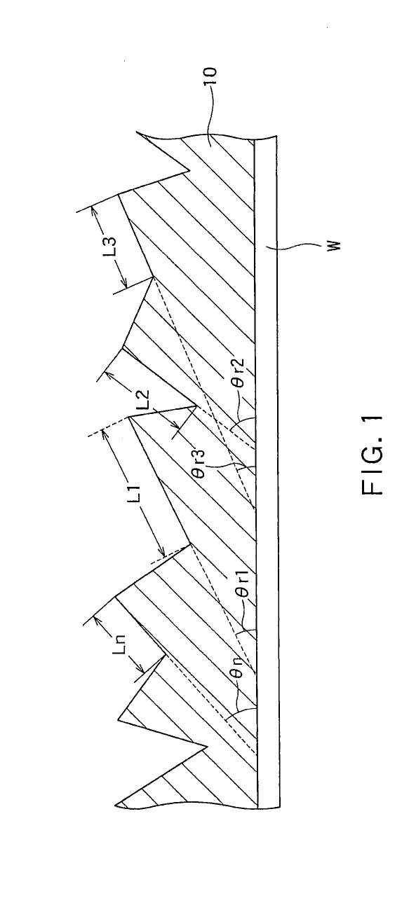

FIG. 1 is a schematic sectional view illustrating an evaluation sample according to an embodiment. The evaluation sample shown in FIG. 1 includes a silicon wafer W, and a foundation film (polysilicon film 10) formed on the silicon wafer W.

An orientation plane (111) is exposed on the surface of each crystal grain that constitutes the polysilicon film 10. The facet planes appear straight in section, and an edge shape thereof is sharp and is hardly rounded. Moreover, as shown in FIG. 1, the angles between the extension of each orientation plane (111) and the surface of the silicon wafer W are a random angle θr1, θr2, . . . , or θrn (n is a natural number equal to or more than 2).

Thus, according to the present embodiment, the evaluation sample having surfaces with various angles θr with the surface of the silicon wafer W is provided. In the present embodiment, the angles Or include at least four or more different angles.

The size of each crystal grain is several μm to several tens of μm, and is preferably about 1 μm to about 10 μm. In FIG. 1, the size of each facet plane indicated by the reference signs L1, L2, . . . , and Ln (n is a natural number equal to or more than 2) is about 5 μm in the present embodiment.

In the present embodiment, the silicon wafer W corresponds to, for example, a substrate. The substrate material is not limited to a semiconductor wafer such as a silicon wafer. A polycrystalline film that has random orientations has only to be formed on the surface of the substrate in the end, so therefore, a substrate made of, for example, a glass or ceramic insulator is also included.

In the present embodiment, the polysilicon film 10 corresponds to, for example, a polycrystalline film. Any crystalline material that can be formed as a film on a monocrystalline substrate surface layer can be used as the material for the polycrystalline film. For example, it is possible to use not only, for example, a nitride film (SiN) but also a metal material such as tungsten (W), copper (Cu), or iron (Fe), and a metal silicide such as titanium silicide (TiSi), cobalt silicide (CoSi), or nickel silicide (NiSi).

In the present embodiment, the orientation plane (111) corresponds to, for example, a specific orientation plane. It should be appreciated that the specific orientation plane is not limited to the orientation plane (111) but also includes, for example, a (110) face or a (112) face.

(2) Manufacturing Method

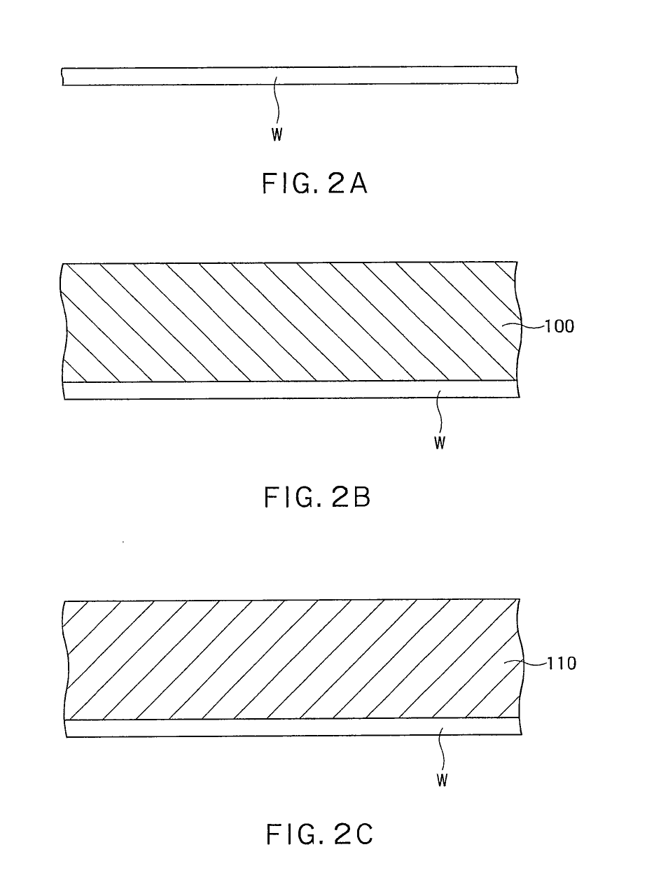

A method of manufacturing an evaluation sample shown in FIG. 1 is described with reference to FIG. 2A to FIG. 2C.

First, as shown in FIG. 2A, a silicon wafer W is prepared. The silicon wafer W is then subjected to rapid thermal chemical vapor deposition (RTCVD), and an amorphous silicon film 100 is thereby formed as shown in FIG. 2B. Further, a polysilicon film 110 is formed as shown in FIG. 2C by an annealing treatment at a temperature of about 1200° C. for about 20 minutes. The size of a crystal grain of the polysilicon film 110 is several μm to several tens of and is preferably about 1 μm to about 10 μm. At this point, the crystal grains that constitute polysilicon have different crystal orientations.

Furthermore, the polysilicon film 110 is treated with a chemical solution. More specifically, the polysilicon film 110 is etched by, for example, a potassium hydroxide (KOH) solution. An orientation plane (111) is thereby solely exposed in each crystal grain. As a consequence, as shown in FIG. 1, an evaluation sample having surfaces with various angles θr1, θr2, . . . , and θrn (n is a natural number equal to or more than 2) with the surface of the silicon wafer W is provided. That is, since the crystal grains are randomly stacked on the silicon wafer W, the surface of the orientation plane (111) of each crystal is also randomly located relative to the surface of the silicon wafer W. The size (see the reference signs L1, L2, . . . , and Ln in FIG. 1 (n is a natural number equal to or more than 2)) of a facet plane in this case is about 5 μm in the present embodiment. If, for example, the silicon wafer W with a diameter of 300 mm is used, the evaluation sample angles θr1, θr2, and θrn include at least four or more different angles (n≧4).

(B) Method of Determining Etching Yield Function

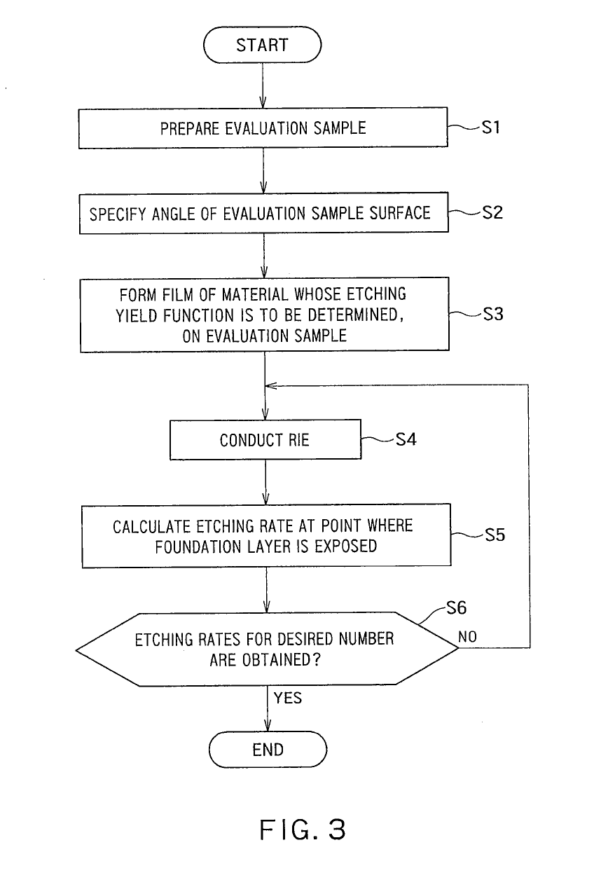

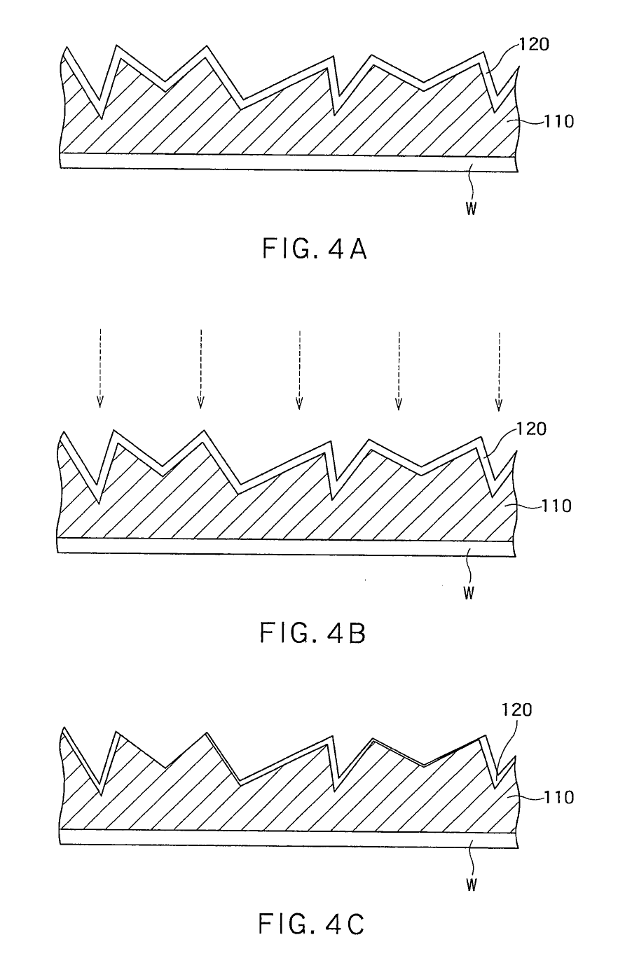

A method of determining a yield function according to one embodiment is described with reference FIG. 3 to FIG. 4C. FIG. 3 is a flowchart showing a general process of determining a yield function according to the present embodiment. FIG. 4A to FIG. 4C are schematic sectional views illustrating the method of determining the yield function shown in FIG. 3.

First, an evaluation sample is prepared (FIG. 3, step S1). An evaluation sample has a film with a large number of (unrounded) inclinations with various angles between its surface and the surface of the substrate. In the present embodiment, the above-mentioned evaluation sample shown in FIG. 1 is used. Here, “unrounded” means that an inclination used as the evaluation sample is not rounded, and a part of an inclination that is not used as the evaluation sample may be rounded.

Multiple positions are then specified in the silicon wafer W (see FIG. 1), and the angles θr1, θr2, . . . , and θrn (n is a natural number equal to or more than 2) (see FIG. 1) of the evaluation sample surface at their respective positions are specified (FIG. 3, step S2). For example, observation by an electron backscattering pattern (EBSP) method can be used as the method to specify the angles. Step 2 does not need to be performed at this stage, but only has to be performed before step 5.

As shown in FIG. 4A, a film 120 of a material whose etching yield function is to be determined is formed with a thickness of about 50 to 100 nm on the evaluation sample (FIG. 3, step S3). When the thickness of the film 120 is 100 nm, the size (the reference signs L1, L2, . . . , and Ln in FIG. 1 (n is a natural number equal to or more than 2)) of the facet plane of the evaluation sample is preferably controlled to be about 5 μm.

Furthermore, as shown in FIG. 4B, the film 120 on the evaluation sample is subjected to RIE for a time t1 (FIG. 3, step S4).

As shown in FIG. 4C, a scanning electron microscope (SEM) for surface observation is then used to confirm whether the foundation of the film 120 is exposed. An etching rate for that specific position is calculated at a point where the foundation layer is exposed (FIG. 3, step S5). For example, suppose that the film formed at the angle θrn of the surface is removed in the time t1. At this moment, the thickness of the film and the angle θrn are used to calculate the etching rate.

The above-mentioned RIE, surface observation, and calculation of the etching rate in step S4 and S5 are repeated until etching rates for a desired number of wafer positions (preferably 4 or more positions) specified in step S2 are obtained (FIG. 3, step S6). For example, suppose that the film formed at the angle θr3 of the surface is removed for a time t2 (>the time t1). At this moment, the thickness of the film and the angle θr3 are used to calculate the etching rate. Suppose that the film formed at the angle θr1 of the surface is removed for a time t3 (>the time t2). At this moment, the thickness of the film and the angle θr1 are used to calculate the etching rate. Such calculations are repeated until the desired amount of etching rates is obtained.

As a comparison, suppose that an apparatus different from an apparatus used in an actual etching process is used to determine the yield function. The yield function is then determined in a condition different from the etching condition of an actual etching apparatus, so an accurate etching yield function cannot be calculated in some cases.

As another comparison, suppose that a sample is used in which a foundation film is formed on a wafer and in which a step is formed in the foundation film by etching such as the RIE method. In this case, only one piece of data can be obtained from one wafer. As a result, the efficiency of determining the yield function deteriorates. Moreover, according to this method, the step constantly changes until it reaches a final point where an angle with maximum etching rate emerges. Therefore, it is difficult to accurately determine whether the step has already changed into the angle which presents a maximum etching rate or not.

According to the present embodiment, an etching yield function can be determined and the evaluation sample can be manufactured by using the same apparatus which is used in the actual fabrication process. Thus, it is possible to obtain a precise yield function that represents the actual etching fabrication process.

Moreover, according to the present embodiment, a large number of etching rates can be nondestructively acquired from a single silicon wafer W, thus enabling the acquisition of an accurate yield function having a large number of data points with a simple process at low cost.

A silicon wafer of the same size with the one that is actually used in manufacture can be used as the silicon wafer for the evaluation sample. For example, when the silicon wafer having a diameter of 300 mm is used in the manufacture, a silicon wafer having a diameter of 300 mm can also be used for the evaluation sample. As a result, it is possible to obtain an etching yield function close to an etching yield function in the actual manufacture.

It is also possible to acquire an in-plane variation of the etching yield function in one silicon wafer. For example, it is possible to obtain an etching yield function from angles formed in the vicinity of the center of the silicon wafer, and obtain an etching yield function from angles formed in the vicinity of the circumference of the silicon wafer. As a result, it is possible to determine an etching yield function with in-plane variation.

(C) Simulation Method

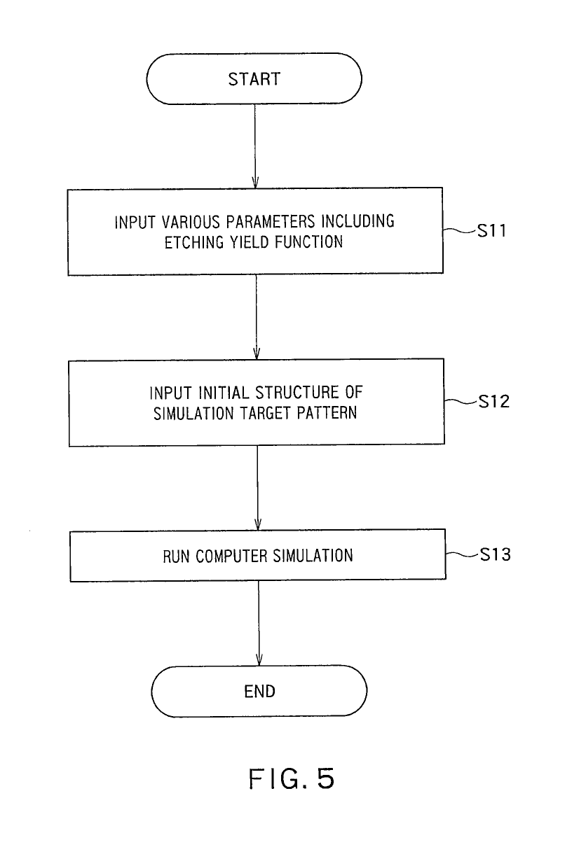

A simulation method according to an embodiment is described with reference to FIG. 5. FIG. 5 is a flowchart showing a general procedure of the simulation method according to the present embodiment.

First, various parameters for a simulation are input to a simulator (not shown) (step S11). These parameters include an etching yield function. In the present embodiment, an etching yield function according to the embodiment described above is used.

An initial structure is then input to the simulator (not shown) (step S12).

Furthermore, the simulator (not shown) runs a computer simulation, and the final structure is output (step S13).

According to the present embodiment, the above-described accurate yield function having a large number of data points is loaded into the computer simulation, and an etching simulation is then run. Therefore, it is possible to use a general-purpose simulator to accurately predict an after-etch structure for various parameter values. Consequently, the development period can be shortened and development cost can be reduced.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of methods and systems described herein may be made without departing from the spirit of the inventions. The accompanying claims and their equivalents are intended to cover such forms or modifications as would fall within the scope and spirit of the inventions.

1. An evaluation sample comprising:
a substrate and a polycrystalline film on the substrate,
wherein the polycrystalline film comprises crystal grains, a specific orientation plane being exposed on the surface of the crystal grains, and
the orientation plane comprises a random angle to the surface of the substrate.

2. The sample of claim 1,
wherein the polycrystalline film is a polysilicon film, and the specific orientation plane is a (111) face.

3. The sample of claim 1,
wherein the material of the polycrystalline film is selected from silicon nitride (SiN), tungsten (W), copper (Cu), iron (Fe), and a metal silicide.

4. The sample of claim 1,
wherein the size of the crystal grain is 1 μm to 10 μm.

5. The sample of claim 1,
wherein the size of a facet plane is about 5 μm.

6. A method of determining an etching yield function, the method comprising:
creating an evaluation sample by forming a polycrystalline film on a substrate and treating the polycrystalline film with a chemical solution to expose a specific orientation plane in the surface of crystal grain in such a manner that the specific orientation plane comprises a random angle to the surface of the substrate;
determining the angle of the evaluation sample;
forming, on the polycrystalline film, a material targeted for etching fabrication;
subjecting a film of the material to an RIE treatment; and
observing whether a foundation material directly under the film of the material is exposed by the RIE treatment, and thereby determining an etching rate in association with each angle.

7. The method of claim 6,
wherein the RIE treatment and the observation are repeated until etching rates of a desired number are obtained.

8. The method of claim 6,
wherein the polycrystalline film is an amorphous silicon film, and the chemical solution is a KOH solution.

9. The method of claim 6,
wherein the polycrystalline film is an amorphous silicon film, and the specific orientation plane is a (111) face.

10. The method of claim 6,
wherein the material of the polycrystalline film is selected from silicon nitride (SiN), tungsten (W), copper (Cu), iron (Fe), and a metal silicide.

11. The method of claim 6,
wherein the size of the crystal grain is 1 μm to 10 μm.

12. The method of claim 6,
wherein the thickness of the film of the material targeted for the etching process is about 100 nm, and
the size of a facet plane is about 5 μm.

13. The method of claim 6,
wherein the angle is determined by an EBSP method.

14. A simulation method comprising:
predicting a surface structure after etching process by use of an etching yield function and an initial structure,
wherein the etching yield function is determined by
determining an angle between a specific orientation plane of a polycrystalline film and a surface of a substrate in an evaluation sample, the evaluation sample comprising the substrate and the polycrystalline film on the substrate, the polycrystalline film comprising crystal grains, the specific orientation plane being exposed on the surface of each of the crystal grains, the angle between the orientation plane and the surface of the substrate being random,
forming, on the polycrystalline film, a material targeted for the etching process,
subjecting the formed film of the material to an RIE treatment, and
observing whether a foundation material directly under the film of the material is exposed by the RIE treatment, and thereby determining an etching rate in association with each of the angles.

15. The method of claim 14,
wherein the RIE treatment and the observation are repeated until etching rates of a desired number are obtained.

16. The method of claim 14,
wherein the polycrystalline film is an amorphous silicon film, and the specific orientation plane is a (111) face.

17. The method of claim 14,
wherein the size of the crystal grain is 1 μm to 10 μm.

18. The method of claim 14,
wherein the thickness of the film of the material targeted for the etching process is about 100 nm, and
the size of a facet plane is about 5 μm.
